(19) United States
(12) Patent Application Publication
(10) Pub. No.: US 2005/0264998 A1
(43) Pub. Date: Dec. 1, 2005

(54) Heat sink assembly

(75) Inventors: Jeffrey W. McCutcheon, Baldwin, WI (US); Sharon L. Ruffing, Oakdale, MN (US)

Correspondence Address: 3M INNOVATIVE PROPERTIES COMPANY, PO BOX 33427, ST. PAUL, MN, 55133-3427, US

(73) Assignee: 3M Innovative Properties Company

(21) Appl. No.: 10/852,780

(22) Filed: May 25, 2004

(51) Int. Cl. H05K 7/20

(52) U.S. Cl. 361/702

(57) ABSTRACT

Heat sink apparatuses comprising a heat sink and a mounting fixture attached to the heat sink are provided. The mounting fixture is selected from the group consisting of dentate mounting fixtures, fenestrated mounting fixtures, and cavitated mounting fixtures. Also provided are heat sink assemblies including devices attached to heat sink apparatuses, methods of mounting devices to heat sink assemblies, and methods of making heat sink apparatuses.

### BACKGROUND

The field of the invention pertains to heat sink assemblies and methods of attaching devices to heat sinks.

Devices such as integrated circuits, capacitors, power amplifiers, and other electronic components generate heat as electric current passes through the device. Generally, this heat must be dissipated as the device may fail if its temperature rises above some critical temperature. In general, the attachment of devices to heat sinks to aid in the dissipation of heat is known.

In practice, a device may be attached to the heat sink first, followed by mounting the device, and optionally the heat sink, to a substrate such as a printed circuit board. Generally, the device must be precisely aligned on, and securely attached to the heat sink to prevent misalignment of the device with the substrate.

Currently, a thermal interface pad is placed between the device and the heat sink and both are held in place by a mechanical device such as a clip in combination with nuts and bolts. Alternatively, thermal transfer tape is used to attach the device to the heat sink. Given the need to prevent air gaps, soft and conformable tapes are used. Generally, these methods do not offer sufficient torque, shear, tensile, or cleavage holding strength when the device is inserted into a substrate. This can result in misalignment between the device and the substrate, and damage to the device during mounting, handling, and use.

### SUMMARY

Briefly, in one aspect, the present invention provides a heat sink apparatus comprising a heat sink having a mounting surface and a mounting fixture attached to the heat sink, wherein the mounting fixture is selected from the group consisting of a dentate mounting fixture, a fenestrated mounting fixture, and a cavitated mounting fixture.

In some embodiments, the heat sink apparatus further comprises an adhesive member comprising a first surface and a second surface, wherein the first surface of the adhesive member is adhered to the mounting surface of the heat sink and the mounting fixture is adhered to at least a portion of the second surface of the adhesive member.

In some embodiments, at least one of the heat sink and the mounting fixture further comprises structural restraining features.

In some embodiments, the mounting fixture is a cavitated mounting fixture further comprising a pressure-invertible dimple.

In another aspect, the present invention provides a heat sink assembly comprising a heat sink having a mounting surface; a mounting fixture attached to the heat sink, wherein the mounting fixture is selected from the group consisting of a dentate mounting fixture, a fenestrated mounting fixture, and a cavitated mounting fixture; and a device attached to the heat sink.

In some embodiments, the heat sink assembly further comprises a substrate, wherein the device is attached to the substrate.

In yet another aspect, the present invention provides a method of mounting a device to a heat sink comprising providing the heat sink apparatus comprising a heat sink and a mounting fixture; aligning the device relative to one or more features of the mounting fixture; and adhering the device to the heat sink apparatus.

In yet another aspect, the present invention provides a method of making a heat sink apparatus comprising providing a heat sink; and attaching at least one mounting fixture selected from the group consisting of a dentate mounting fixture, a fenestrated mounting fixture, and a cavitated mounting fixture to the heat sink.

In some embodiments, the mounting fixture is attached to the heat sink with an adhesive.

In some embodiments, the mounting fixture is attached to the heat sink with one or more structural restraining features.

In some embodiments, the mounting fixture is wrapped around one or more edges of the heat sink.

The above summary of the present invention is not intended to describe each embodiment of the present invention. The details of one or more embodiments of the invention are also set forth in the description below. Other features, objects, and advantages of the invention will be apparent from the description and from the claims.

### BRIEF DESCRIPTION OF THE DRAWINGS

FIG. 1A illustrates an exploded view of an exemplary heat sink apparatus of the prior art.

FIG. 1B illustrates the heat sink apparatus of FIG. 1A mounted to a substrate.

FIG. 2A illustrates an exploded view of a heat sink apparatus with a dentate mounting fixture in accordance with an embodiment of the invention.

FIG. 2B illustrates the heat sink apparatus of FIG. 2A mounted to a substrate.

FIGS. 3A-3D illustrate exemplary heat sinks having structural restraining features in accordance with embodiments of the present invention.

FIG. 4 illustrates a heat sink apparatus with a dentate mounting fixture in accordance with another embodiment of the invention.

FIGS. 5A-5D illustrate a variety of edge patterns in accordance with some embodiments of the invention.

FIG. 6 illustrates a heat sink apparatus with a fenestrated mounting fixture in accordance with an embodiment of the invention.

FIG. 7 illustrates a heat sink apparatus with a cavitated mounting fixture in accordance with an embodiment of the invention.

FIG. 8A illustrates a heat sink apparatus with a dimpled cavitated mounting fixture prior to compression of the dimple, in accordance with an embodiment of the invention.

FIG. 8B illustrates a heat sink apparatus with a dimpled cavitated mounting fixture after compression of the dimple, in accordance with an embodiment of the invention.

FIG. 9 illustrates a plurality of mounting fixtures formed from a web.

FIG. 10 illustrates a plurality of mounting fixtures formed from a web including score lines.

FIG. 11 illustrates a scored mounting fixture folded over an edge of a heat sink in accordance with an embodiment of the present invention.

### DETAILED DESCRIPTION

In some applications, it is desirable to attach a device to a heat sink prior to mounting the device on a substrate, such as, e.g., a printed circuit board (PCB). For example, one method of mounting a device and a heat sink to a printed circuit board comprises attaching a device to the mounting surface of a heat sink, temporarily mounting the device to the PCB by mating pins on the device, and optionally on the heat sink, with corresponding holes in the PCB, and wave soldering the device to the PCB.

Generally, the pins substantially align with the holes in the PCB. If the pins are not substantially aligned, the pins and/or the device may become damaged during the attachment or subsequent use of the device. Generally, when the pins on the device are inserted into the holes in the PCB, forces (e.g., shear, torsion, tensile, and cleavage forces) may arise at the interface between the device and the mounting surface of the heat sink. These forces may shift the position of the device and its pins, resulting in misalignment with the mounting holes and ultimately damage to the mounting pins. These forces may also separate the device from the mounting surface of the heat sink. This separation can lead to poor thermal performance and reduce device reliability.

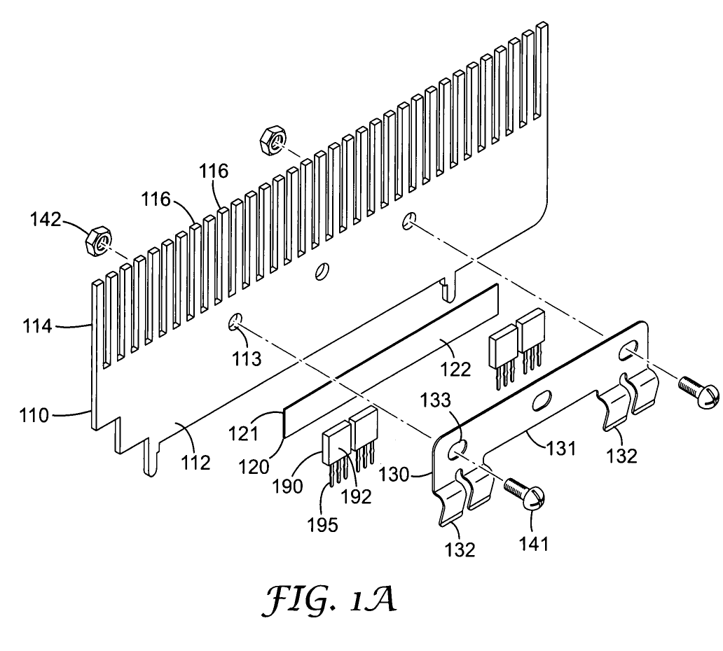

Generally, it is desirable to secure the device to the heat sink. Referring to FIGS. 1A and 1B, a prior art heat sink apparatus is shown. Generally, a thermally conductive material is positioned between a device (e.g., an integrated circuit, capacitor, power amplifier, power transistor device, FETS, or MOSFETS) and the mounting surface of a heat sink. A mechanical mechanism (e.g., a spring clip or a screw) is then used to hold the device in position as the device and heat sink apparatus are mounted to a substrate.

More specifically, FIGS. 1A and 1B illustrate heat sink apparatus 100 including heat sink 110 having mounting surface 112 and heat-dissipating structure 114. Heat-dissipating structure 114 comprises fins 116. Generally, a heat sink may have a plurality of mounting surfaces. In some embodiments, heat sink 110 has a second mounting surface opposite mounting surface 112.

First surface 121 of thermally conductive material 120 is adhered to mounting surface 112. Mounting bracket 130, comprising mounting bar 131 and spring clips 132, is positioned on heat sink 110 by aligning mounting bracket mounting holes 133 with heat sink mounting holes 113. Devices 190 are positioned adjacent second surface 122 of material 120, with one device 190 under each spring clip 132. Mounting pins 195 extend from each device 190. Generally, the location of each spring clip 132 aids in positioning and aligning a device. Bolts 141 are then passed through mounting holes 113 and 133 and nuts 142 are threaded onto bolts 141, securing mounting bracket 130 to heat sink 110. A spring force biases spring clip 132 against exposed surface 192 of device 190, securing it in place.

Referring to FIG. 1B, mounting pins 195 on device 190 are aligned with substrate mounting holes 183 on substrate 180. Force F is applied to heat sink apparatus 100 and/or substrate 180 to securely insert mounting pins 195 into substrate mounting holes 183. During this mounting process, device 190 is subjected to forces that may shift the position of device 190 relative to heat sink 110. In turn, this may result in misalignment of, and damage to mounting pins 195, as well as separation of device 190 from mounting surface 112 of heat sink 110. The spring force applied by mounting bracket 130 is intended to minimize this shifting.

While prior art mechanical mechanisms address some of the problems encountered when mounting devices and a heat sink to a substrate, further improvements are desired. For example, prior art mechanical mechanisms generally require numerous parts that must be positioned and held in place, along with the devices, while screws or bolts are threaded in place. This may become particularly cumbersome when multiple devices (e.g., 2, 4, 8 or more devices) are mounted on a single heat sink. Also, while clips may aid in aligning the devices relative to the heat sink, lateral misalignment of the devices under the clips may still occur, resulting in misalignment of the mounting pins with the mounting holes. Finally, prior art mechanical mechanisms such as screws and spring clips provide restraint perpendicular to the mounting surface of the heat sink, but may not provide sufficient lateral support. Thus, as torsional forces arise during mounting, the devices may twist resulting in misalignment of the mounting pins and the mounting holes. This problem is exacerbated when multiple devices are present on a single heat sink.

In some embodiments, the present invention aids in the lateral and vertical alignment of devices on the mounting surface of a heat sink. In some embodiments, the present invention restrains the motion of a device relative to the mounting surface of a heat sink as the mounting pins on the device and heat sink are inserted into the holes on a substrate, and/or as the apparatus and device are handled or used. In some embodiments, motion of the device parallel to the mounting surface of the heat sink is restrained. In some embodiments, motion of the device perpendicular to the mounting surface of the heat sink is restrained.

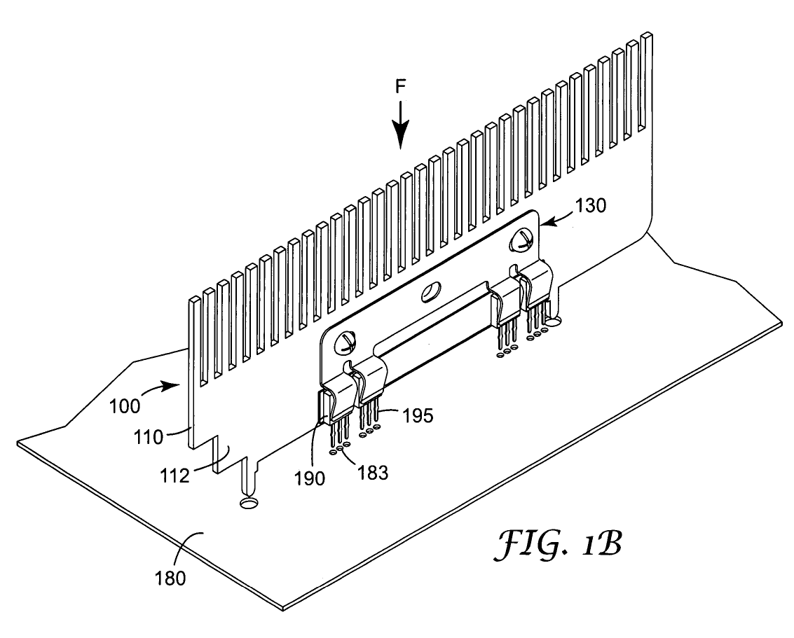

Referring to FIGS. 2A and 2B, an exemplary heat sink apparatus of the present invention is illustrated. Heat sink apparatus 200 includes heat sink 210, adhesive member 250, and dentate mounting fixture 260. Heat sink 210 comprises mounting surface 212 and heat-dissipating structure 214 comprising fins 216. First surface 251 of adhesive member 250 is adhered to mounting surface 212 of heat sink 210. Dentate mounting fixture 260 is adhered to second surface 252 of adhesive member 250.

Generally, the shape of a heat sink can vary widely depending, for example, on the heat load, the size and number of devices mounted to it, and the space available. Any known heat sink including, e.g., heat spreaders and heat dissipaters, can be used with the present invention.

In some embodiments, adhesive member 250 comprises a layer of adhesive. The adhesive may be applied in any form including, e.g., solids, liquids, pastes, foams, or gels. In some embodiments, the adhesive may be curable (e.g., moisture curable, reactively curable (e.g., two-part adhesives), thermally curable, or actinic radiation (e.g., UV) curable). In some embodiments, adhesive member 250 comprises a laminating adhesive (e.g., a free-film adhesive). In some embodiments, adhesive member 250 comprises a double-sided adhesive tape (i.e., a carrier (e.g., paper, polymer film, metal) with an adhesive on both major surfaces of the carrier). In some embodiments, adhesive member 250 is thermally conductive and/or electrically insulative. In some embodiments, thermally conductive filler(s) may be added to materials of this invention to increase the thermal conductivity. Addition of thermally conductive fillers may affect the mechanical and physical properties of the invention. One skilled in the art can adjust formulas and filler amounts and filler surface treatment to provide both thermal conductivity and suitable adhesive performance.

In some embodiments, the thermally conductive fillers are selected from a variety of materials having a bulk conductivity of at least 5 Watts/meter-Kelvin (W/mK) (in some embodiments, at least 150 W/mK, and even at least 1000 W/mK) as measured according to ASTM D1530. Exemplary thermally conductive fillers include ceramics (e.g., aluminum oxide, boron nitride, silicon carbide, and aluminum nitride), metals (e.g., nickel, silver, gold, copper, iron, and aluminum), magnesium hydroxide, aluminum hydroxide, carbon, diamond, and the like.

In some embodiments, the conductive fillers may comprise fibers, particulates, platelets, needles, whiskers, nanoparticles (e.g., solid and/or hollow nanospheres), spheres, flakes, agglomerates, and the like. In some embodiments, the fillers comprise particles coated with a thermally conductive material (e.g., a metal). Generally, the choice of shape is dependent upon the rheology of the selected adhesive resin and ease of processing of the final resin/particle mix.

Generally, the larger the particle size of the filler, the higher will be the resultant final conductivity. Generally, a mixture of particle sizes can result in improved packing density that improves the resultant conductivity. Combinations of different fillers may be used. For example, a combination of fillers may provide equivalent thermal performance at reduced costs by substituting a portion of an expensive filler (e.g., boron nitride) with a cheaper filler (e.g., silicon carbide).

Fillers may be available in several crystal types (e.g., hexagonal and rhombic boron nitride) and, generally, the type of crystal chosen will depend upon the thermal conductivity of the crystal (including the anisotropic nature of the conductivity along different crystal axes), the effect of crystal type on final mechanical properties, and cost. Fillers often have anisotropic thermal conductivity along various crystal planes; therefore, filler orientation may be used to enhance thermal performance. In some embodiments, the filler has a bulk thermal conductivity in one direction of at least 5 W/mK (in some embodiments, at least 150 W/mK, or even at least 1000 W/mK).

Particle size and distribution may also affect mechanical properties, and particle size selection can take into account the requirements for good final adhesive strength. Generally, the particle size of the filler (or mixture of fillers) and particle loading are selected to produce suitable thermal conductance while retaining adequate mechanical properties. Particle size is the length of the major axis of a particle. In some embodiments, the particle size of the filler is greater than 2 microns (in some embodiments, greater than 5 microns, or even greater than 10 microns.) In some embodiments, the particle size of the filler is less than 200 microns (in some embodiments, less than 100 microns, and even less than 50 microns).

Dentate mounting fixture 260 comprises teeth 261 and bridge 263. Gaps 262 are defined by the space adjacent a tooth, and are bounded by bridge 263 and at least one tooth 261. Dentate mounting fixture 260 is adhered to at least a portion of second surface 252 of adhesive member 250. Generally, bridge 263 and teeth 261 are adhered to adhesive member 250. In some embodiments, exposed adhesive may extend beyond the edges of dentate mounting fixture 260 and the areas exposed by gaps 262.

Device 290 is substantially aligned within gap 262 and adhered to at least a portion of second surface 252 of adhesive member 250 located within gap 262. Generally, the location and dimensions of gap 262 are determined by, e.g., the dimensions of device 290 and the desired location of device 290 relative to a substrate to which it will ultimately be mounted. In some embodiments, a gap is wide enough to accommodate one device. In some embodiments, a gap is wide enough to accommodate two or more devices.

Top edge 264 of gap 262 aids in the vertical alignment of device 290 relative to lower edge 213 of heat sink 210. Side edges 265 and 266 aid in the lateral alignment of device 290 relative to mounting surface 212 of heat sink 210. In some embodiments, device 290 will be positioned adjacent to, and substantially aligned with one or more teeth 261, and optionally bridge 263. In some embodiments, the device is less than about 5 millimeters (mm) from at least one edge (in some embodiments, less than about 1 mm, or even less than 0.1 mm). In some embodiments, device 290 may abut one or more edges. Generally, the teeth are sized and spaced to allow one or more devices to be positioned within a gap.

Referring to FIG. 2B, mounting pins 295 on device 290 are aligned with substrate mounting holes 283 on substrate 280. Force F is applied to heat sink apparatus 200 and substrate 280 to securely insert mounting pins 295 in substrate mounting holes 283. During this mounting process, device 290 is subjected to shear forces S and torsion forces T. In some embodiments, tension and cleavage forces may also be present. Generally, teeth 261 and, optionally, bridge 263 resist displacement of device 290 and minimize motion and the corresponding misalignment of mounting pins 295 relative to mounting holes 283.

In some embodiments, the mounting fixture can be attached to the heat sink using a single-sided tape. For example, a piece of single-sided tape may be adhered to both the mounting fixture and the heat sink securing them together. In some embodiments, the single-sided tape may cover a portion of the devices.

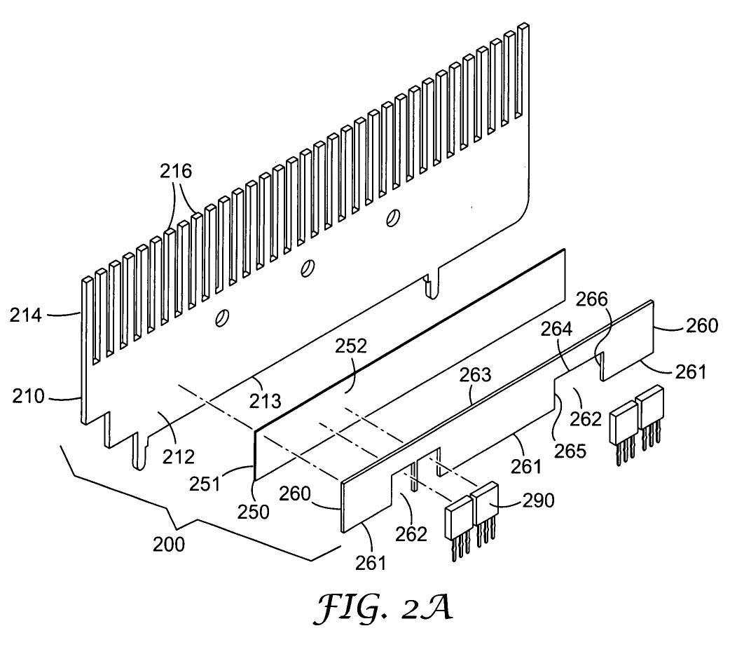

In some embodiments, the mounting fixture may be attached to the heat sink using mechanical retention features. Generally, the retention features provide snap, press, compression, or interference fit. Referring to FIGS. 3A-3D, additional exemplary heat sink apparatuses of the present invention are illustrated. Any known structural restraining features may be used including tabs, pins, and clips.

Referring to FIG. 3A, heat sink apparatus 301 includes heat sink 310 and dentate mounting fixture 366. Heat sink 310 and dentate mounting fixture 366 comprise corresponding structural restraining features which allow dentate mounting fixture 366 to be attached to mounting surface 312. The structural restraining features comprise flange 311 and corresponding edge 361, wherein edge 361 is positioned between flange 311 and mounting surface 312.

Referring to FIG. 3B, heat sink apparatus 302 includes heat sink 310 and dentate mounting fixture 367. Heat sink 310 and dentate mounting fixture 367 comprise corresponding structural restraining features which allow dentate mounting fixture 367 to be attached to mounting surface 312. The structural restraining features comprise opening 313 and tab 363, wherein tab 363 may be inserted into opening 313.

Referring to FIG. 3C, heat sink apparatus 303 includes heat sink 310 and dentate mounting fixture 368. Heat sink 310 and dentate mounting fixture 368 comprise corresponding structural restraining features which allow dentate mounting fixture 368 to be attached to mounting surface 312. The structural restraining features comprise post 314 and corresponding hole 364, wherein post 314 may be inserted into hole 364. Generally, any known post shape may be used to promote engagement in the hole. Exemplary post shapes include Christmas tree, conical, button, and mushroom. In some embodiments, the post may have serrated edges.

Referring to FIG. 3D, heat sink apparatus 304 includes heat sink 310 and dentate mounting fixture 369. Heat sink 310 and dentate mounting fixture 369 comprise corresponding structural restraining features which allow dentate mounting fixture 369 to be attached to mounting surface 312. The structural restraining features comprise lip 315, which wraps around an edge of heat sink 310.

In some embodiments, additional structural features such as hooks, loops, or protrusions may be used. In some embodiment, the location of the retention features is reversed, e.g., posts may be located on the heat sink with corresponding holes in the mounting fixture. In some embodiments, the heat sink apparatus comprises a plurality of structural restraining features. In some embodiments, two or more different structural restraining features are present.

Generally, any size, shape, and location of structural restraining features may be used. In some embodiments, the use of structural restraining features allows for easier removal and reuse of the mounting fixture, and or the heat sink.

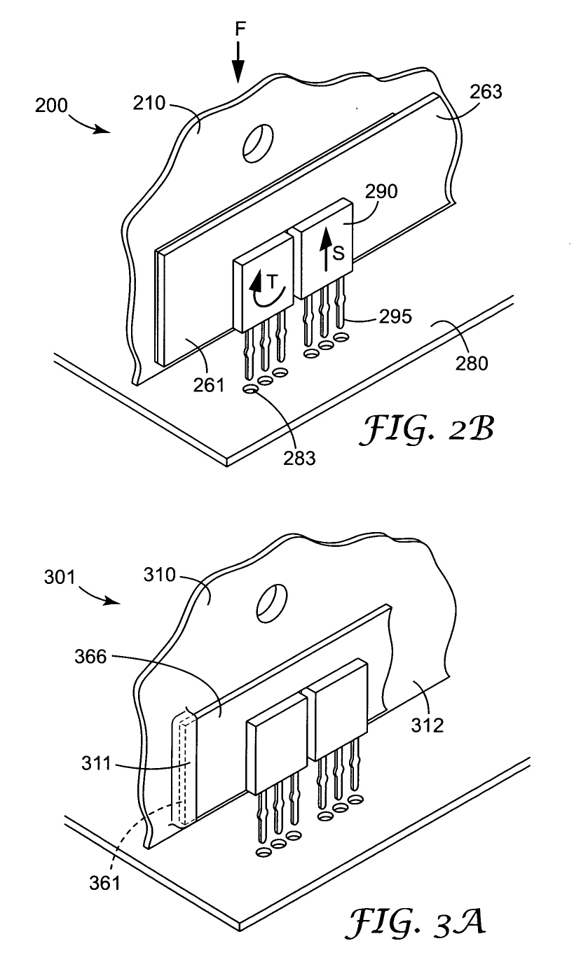

Referring to FIG. 4, another exemplary heat sink apparatus of the present invention is illustrated. Heat sink apparatus 400 includes heat sink 410, adhesive member 450 adhered to mounting surface 412, and dentate mounting fixture 460 adhered to adhesive member 450.

Dentate mounting fixture 460 comprises teeth 461 and bridge 463. Gaps 462 are defined by the space adjacent a tooth, and are bounded by bridge 463 and at least one tooth 461. Dentate mounting fixture 460 is adhered to at least a portion of adhesive member 450. In some embodiments, substantially all of dentate mounting fixture 460 is adhered to adhesive member 450. In some embodiments, only a portion of dentate mounting fixture 460 is adhered to adhesive member 450.

Thermally conductive material 470 is positioned within gaps 462. In some embodiments, thermally conductive material 470 is electrically insulative. In some embodiments, the thermally conductive material comprises a thermally conductive adhesive. In some embodiments, the thermally conductive material comprises a single layer. In some embodiments, the thermally conductive material comprises a plurality of layers (e.g., 2, 3, or more layers.) For example, thermally conductive material 470 may comprise three layers: a first adhesive layer, a thermally conductive layer, and a second adhesive layer. In some embodiments, the first adhesive layer is thermally conductive and, optionally, electrically insulative. In some embodiments, the second adhesive layer is thermally conductive and, optionally, electrically insulative. In some embodiments, the thermally conductive layer is electrically insulative.

One or more devices 490 are substantially aligned within gap 462 and adhered to at least a portion of thermally conductive material 470. In some embodiments, device 490 is adhered directly to conductive material 470. In some embodiments, a separate adhesive (e.g., a liquid adhesive or a layer of adhesive) is used to adhere device 490 to thermally conductive material 470.

Generally, the location and dimensions of gap 462 is determined by, e.g., the dimensions of device 490 and the desired location of device 490 relative to a substrate to which it will ultimately be mounted. Top edge 464 of gap 462 aids in the vertical alignment of device 490 relative to lower edge 413 of heat sink 410. Side edges 465 and 466 aid in the lateral alignment of device 490 relative to mounting surface 412 of heat sink 410.

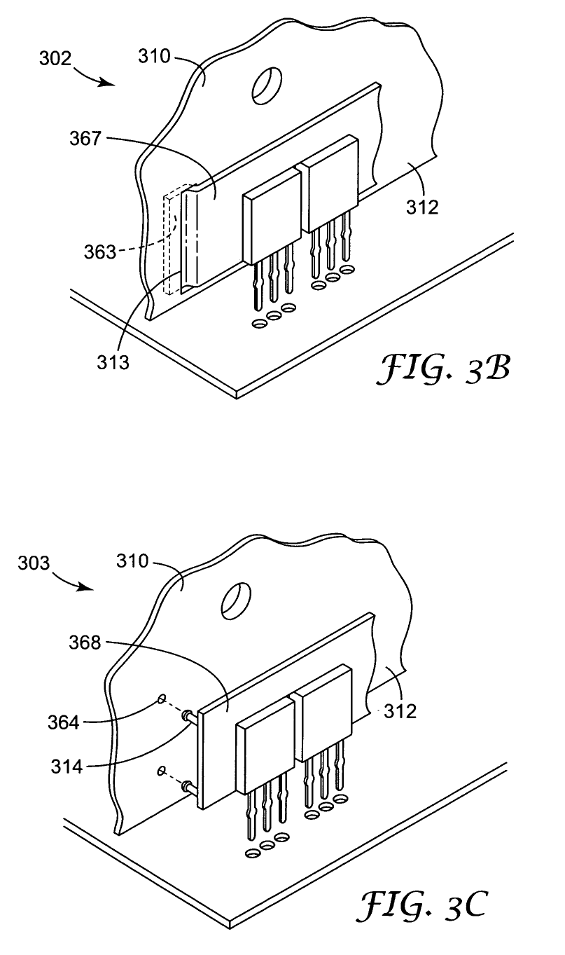

In the preceding figures, the top and side edges of the gaps are shown as substantially straight. However, any known shape may be used. For example, sawtooth, curved, waved, and dentate edge patterns are shown in FIGS. 5A, 5B, 5C, and 5D, respectively. In some embodiments, a different edge shape will be used on the top edge compared to the side edges. In some embodiments, a different edge shape may be used on one side edge relative to the other side edge.

In some embodiments, the edge shape may be selected to enhance the compression fit of a device within a gap. That is, the edge shape may be selected such that a portion of the edge must be compressed as the device is inserted in the gap. The compression of the edges will result in lateral forces being exerted on the corresponding edges of the device that will aid in holding the device in place. Edge shape may also be selected to enhance the resistance to shear and torsion forces. In some embodiments, the edge shape may be selected to increase resistance to torsion forces at the comers of a device.

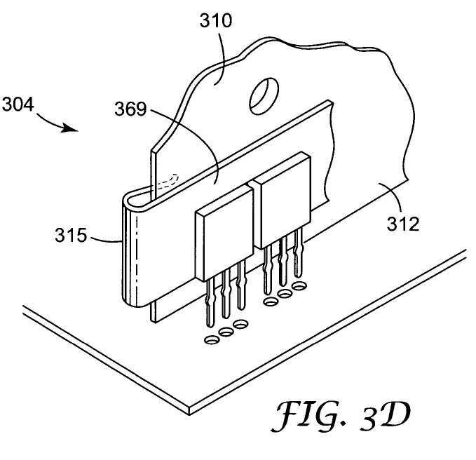

Referring to FIG. 6, a fenestrated mounting fixture 660 according to an embodiment of the present invention is illustrated. Fenestrated mounting fixture 660 comprises windows 662 bounded by upper rail 663, lower rail 665, and stiles 661. Fenestrated mounting fixture 660 may be attached to the heat sink with an adhesive member and/or one or more structural restraining features. One or more devices may be aligned within a window and adhered to the mounting surface.

In some embodiments, at least a portion of the adhesive member is present within window 662 of fenestrated mounting fixture 660, and a device is adhered to the adhesive member. In some embodiments, a thermally conductive material is present within window 662, and the device is adhered to the thermally conductive material.

Generally, the location and dimensions of windows 662 are determined by, e.g., the dimensions of the devices and the desired location of the devices relative to a substrate to which it will ultimately be mounted. Top rail 663 and lower rail 665 of window 662 aid in the vertical alignment of a device relative to the lower edge of a heat sink. Stiles 661 aid in the lateral alignment of a device relative to the mounting surface of a heat sink. In some embodiments, a device will be positioned adjacent to, and substantially aligned with one or more rails or stiles. In some embodiments, a device may abut one or more rails or stiles.

Generally the edge shape of each rail and stile may be independently selected. Any known edge shape may be used. In some embodiments, edge shape may be selected to enhance the compression fit of a device within a gap. In some embodiments, edge shape may be selected to enhance resistance to shear and/or torsion forces.

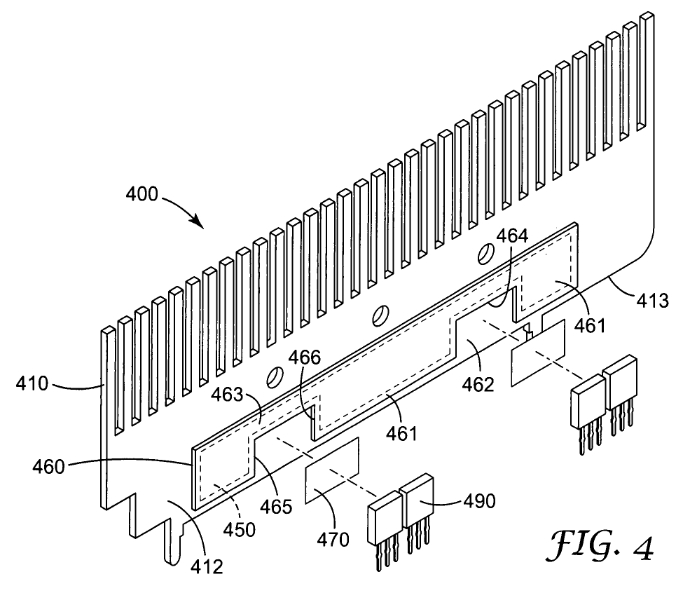

Referring to FIG. 7, cavitated mounting fixture 760, according to an embodiment of the present invention, is shown. Cavitated mounting fixture 760 comprises cavity 762 bounded by bridge 763, edges 765 and 766, and cover 767. In some embodiments, a cavitated mounting fixture comprises a plurality of cavities. Cavitated mounting fixture 760 may be adhered to the heat sink and/or attached using structural restraining features. One or more devices may be aligned within and inserted into cavity 762. In some embodiments, at least a portion of the adhesive member is present within cavity 762 of cavitated mounting fixture 760, and a device is adhered to the adhesive member. In some embodiments, a thermally conductive material is present within cavity 762, and a device is adhered to the thermally conductive material.

Generally, the location and dimensions of cavities 762 are determined by, e.g., the dimensions of the devices and the desired location of the devices relative to a substrate to which it will ultimately be mounted. Bridge 763 aids in the vertical alignment of device 790 relative to the lower edge of a heat sink. Edges 765 and 766 aid in the lateral alignment of a device relative to the mounting surface of a heat sink. In some embodiments, the device will be positioned adjacent to, and substantially aligned with bridge 763 and/or one or more of edges 765 and 766. In some embodiments, the device may abut one or more of bridge 763 and edges 765 and 766.

In some embodiments, cover 767 aids in reducing separation of device 790 from the mounting surface of the heat sink. In some embodiments, bridge 763 and edges 765 and 766 aid in restraining device 790, which reduces motion and misalignment of the device during mounting and use.

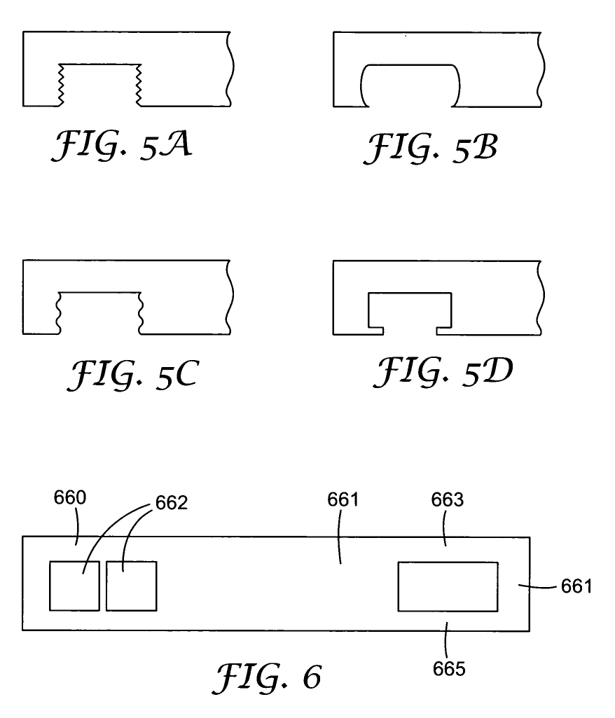

Referring to FIGS. 8A and 8B, another exemplary heat sink apparatus of the present invention is illustrated. Cavitated mounting fixture 860 comprises cavity 862 bounded by a bridge (not shown), edges 865 and 866, and cover 867. Cover 867 comprises pressure-invertible dimple 868, which extends away from mounting surface 812. Cavitated mounting fixture 860 is adhered to adhesive member 850, which is adhered to heat sink 810. In some embodiments, a cavitated mounting fixture may be attached to a heat sink using structural retaining features. Device 890, comprising pins 895, is aligned within and inserted into cavity 862. In some embodiments, device 890 is adhered to heat sink 810.

In some embodiments, adhesive member 850 is thermally conductive and, optionally, electrically insulative. In some embodiments, at least a portion of adhesive member 850 is present within cavity 862 of cavitated mounting fixture 860, and device 890 is adhered to adhesive member 850. In some embodiments, a thermally conductive material is present within cavity 862, and device 890 is adhered to the thermally conductive material.

Referring to FIG. 8B, pressure-invertible dimple 868 is compressed and at least partially inverted such that a least a portion of dimple extends towards mounting surface 812. In some embodiments, when dimple 868 is in the extended position, device 890 will be easier to insert into cavity 862. In some embodiments, when dimple 868 is compressed, dimple 868 will aid in reducing separation of device 890 from heat sink 810. In some embodiments, cavitated mounting fixture 860 will comprise a plurality of dimples. In some embodiments, individual dimples may be selectively compressed to create cavities.

Generally, mounting fixtures and devices may be attached to one or more surfaces of a heat sink. In some embodiments, mounting fixtures and devices are attached to opposing surfaces of a heat sink.

The mounting fixtures of the present invention may comprise any known material including, for example, metal, paper, ceramic, rubber or elastomers, fiberglass, wood, polymeric films, and combinations thereof. In some embodiments, the mounting fixture comprises a polymeric film. In some embodiments, the polymeric film comprises polyester, polyamide, polyimide, polyolefin (e.g., polyethylene or polypropylene), polymethylmethacrylate (PMMA), polystyrene, ABS, PVC, and/or polycarbonate. In some embodiments, the material may be foamed. Generally, the material(s) comprising the mounting fixture may be selected based on, for example, mechanical properties (e.g., tensile strength, compressive strength, and bending stiffness), density, conductive properties (e.g., thermal conductivity and/or electrical conductivity), and cost. Generally, materials having higher compressive strength and/or bending stiffness are preferred. In some embodiments, the mounting fixture comprises multiple layers.

The mounting fixtures of the present invention may be of any thickness. Generally, the thickness of the mounting fixture is less than the thickness of the devices being mounted to the heat sink. In some embodiments, the thickness of the mounting fixture is selected such that the top surface of the fixture is further from the mounting surface of the heat sink then are the pins on the device. In some embodiments, the combined thickness of the mounting fixture and the adhesive layer used to mount the fixture to the heat sink is selected such that the top surface of the fixture is further from the mounting surface of the heat sink then are the pins on the device. In some embodiments, the thickness of the mounting fixture is greater than about 10 microns (μm) (in some embodiments, greater than about 100 μm, greater than about 0.5 millimeter (mm), or even greater than about 2 mm). In some embodiments, the thickness of the mounting fixture is less than about 10 mm (in some embodiments, less than about 5 mm, or even less than about 3 mm).

The mounting fixture of the present invention can be formed by any known process. For example, in some embodiments, the mounting fixtures may be formed by casting or extruding a polymeric film and subsequently punching or die-cutting teeth, gaps, and or windows into the film. In some embodiments, the mounting fixtures may be formed by blow molding, extrusion molding, compression molding, injection molding, stamping, laser cutting, thermo-forming, etching, and the like.

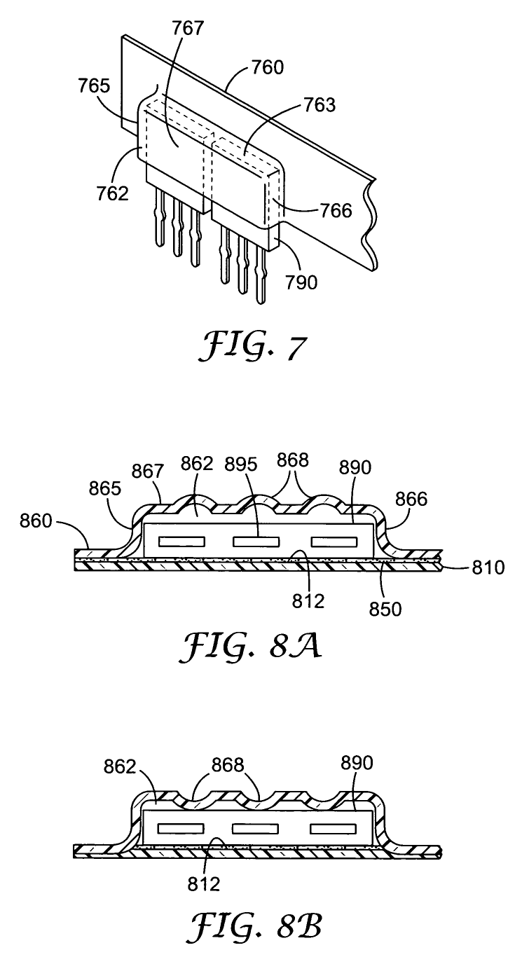

In some embodiments, the mounting fixtures can be formed from a web of material, e.g., a polymeric film. In some embodiments, a plurality of mounting fixtures can be formed in the web of material as illustrated in FIG. 9. Referring to FIG. 9, openings 905 can be formed in substrate 900 by, e.g., die cutting. Substrate 900 may then be slit along lines 911 and 912 to form individual dentate mounting fixtures.

In some embodiments, mounting fixtures of the present invention can be formed with an integral adhesive member by applying (e.g., coating, or extruding) an adhesive (e.g., a thermally conductive adhesive) onto a polymeric film. In some embodiments, the adhesive and polymeric film may be co-extruded. In some embodiments, the adhesive may be laminated to the polymeric film.

In some embodiments, one or more adhesive members may be applied to the mounting surface of a heat sink. Then, one or more mounting fixtures (e.g., dentate, fenestrated, and/or cavitated mounting fixtures) may be applied to one or more of the adhesive members. One or more devices may then be aligned with a gap, window, or cavity and adhered to the mounting surface. In some embodiments, the device will be adhered to the adhesive member. In some embodiments, a thermally conductive material will be positioned within a gap, window, or cavity and adhered to the mounting surface of the heat sink. One or more devices may then be aligned with a gap, window, or cavity and adhered to the thermally conductive material.

In some embodiments, a thermally conductive material may be applied to the mounting surface of the heat sink. In some embodiments, one or more adhesive members may be aligned with the thermally conductive material and adhered to the heat sink. One or more mounting fixtures may then be adhered to the adhesive member(s).

In some embodiments, an adhesive member may be applied to the mounting fixture and the adhesive member and mounting fixture adhered to the mounting surface of the heat sink. In some embodiments, both mounting fixture(s) and device(s) may be adhered to an adhesive member and subsequently adhered to the heat sink. In some embodiments, a thermally conductive material may be adhered to a device and the thermally conductive material and device subsequently adhered to the heat sink.

Generally, once the devices are adhered to the heat sink with the aid of the mounting fixture, the devices and heat sink are aligned with and mounted to a substrate (e.g., a PCB). In some embodiments, the device(s) and, optionally, the heat sink are attached (e.g., welded or soldered (e.g., wave soldered)) to the substrate. In some embodiments, the mounting fixture is removed after the device is attached to the substrate.

In some embodiments, mounting fixtures and devices may be attached to both major surfaces of a heat sink. In some embodiments, two separate mounting fixtures may be attached to opposing major surfaces of a heat sink. In some embodiments, a single mounting fixture may be applied to the heat sink such that gaps, windows, and or cavities are present on opposing surfaces of the heat sink.

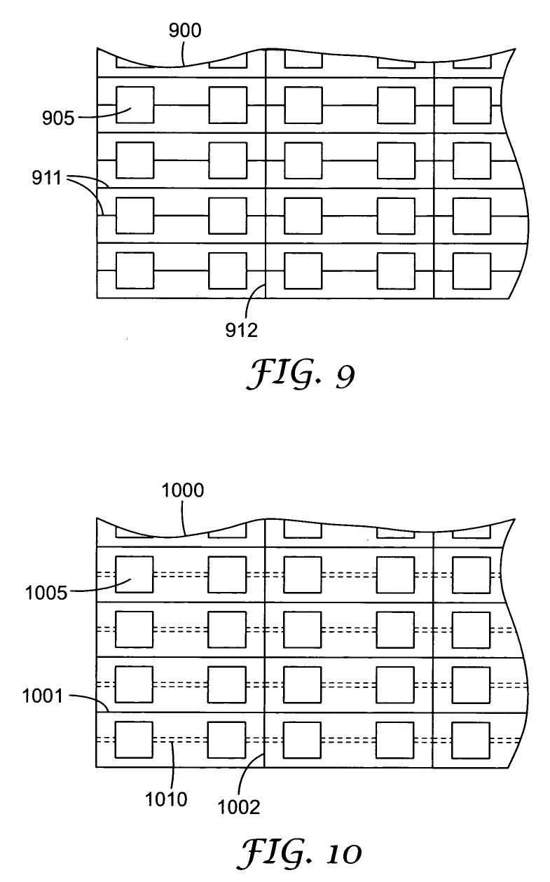

Referring to FIG. 10, a web of mounting fixtures is illustrated. Openings 1005 are formed in substrate 1000 by, e.g., die-cutting. Substrate 1000 is cut along solid lines 1001 and 1002 to form individual mounting fixtures. Optionally, score or fold line 1010 may be formed by, e.g., scoring or perforating substrate 1000.

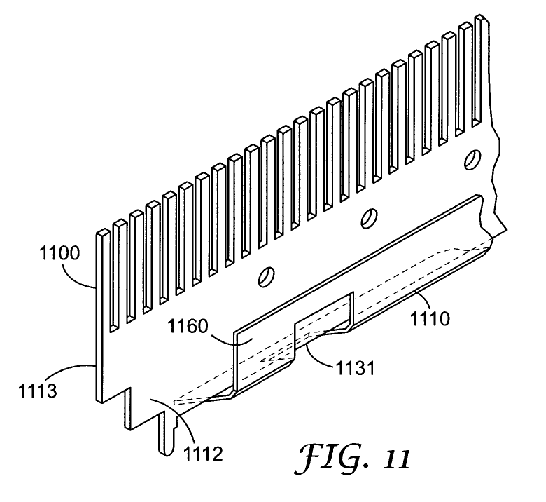

Referring to FIG. 11, mounting fixture 1160 is illustrated. Mounting fixture 1160 is folded along score line 1110 and wrapped around lower edge 1131 of heat sink 1100. In some embodiments, the mounting fixture may be formed to wrap around a side edge of a heat sink. Mounting fixture 1160 is attached to opposing major surfaces 1112 and 1113 of heat sink by, e.g., adhesive members and/or structural restraining features.

Various modifications and alterations of this invention will become apparent to those skilled in the art without departing from the scope and spirit of this invention.

1. A heat sink apparatus comprising
a heat sink having a mounting surface; and
a mounting fixture attached to the heat sink, wherein the mounting fixture is selected from the group consisting of a dentate mounting fixture, a fenestrated mounting fixture, and a cavitated mounting fixture.

2. The heat sink apparatus of claim 1, further comprising an adhesive member comprising a first surface and a second surface, wherein the first surface of the adhesive member is adhered to the mounting surface of the heat sink and the mounting fixture is adhered to at least a portion of the second surface of the adhesive member.

3. The heat sink apparatus of claim 2, wherein the adhesive member comprises a thermally conductive adhesive.

4. The heat sink apparatus of claim 1, wherein at least one of the heat sink and the mounting fixture further comprises a structural restraining feature.

5. The heat sink apparatus of claim 4, wherein the structural restraining feature is selected from the group consisting of posts, holes, flanges, lips, openings, tabs, clips, and combinations thereof.

6. The heat sink apparatus of claim 1, further comprising single-sided tape adhered to the heat sink and the mounting fixture.

7. The heat sink apparatus of claim 1, wherein the mounting fixture is a dentate mounting fixture comprising a bridge, a tooth, and a gap.

8. The heat sink apparatus of claim 7, further comprising a thermally conductive material positioned within the gap.

9. The heat sink apparatus of claim 8, wherein at least a portion of the mounting fixture is adhered to the thermally conductive material.

10. The heat sink apparatus of claim 7, further comprising an adhesive member comprising a first surface and a second surface, wherein the first surface of the adhesive member is adhered to the mounting surface of the heat sink and the mounting fixture is adhered to at least a portion of the second surface of the adhesive member.

11. The heat sink apparatus of claim 1, wherein the mounting fixture is a fenestrated mounting fixture comprising a window, a rail, and a stile.

12. The heat sink apparatus of claim 11, further comprising a thermally conductive material positioned within the window.

13. The heat sink apparatus of claim 12, wherein at least a portion of the mounting fixture is adhered to the thermally conductive material.

14. The heat sink apparatus of claim 11, further comprising an adhesive member comprising a first surface and a second surface, wherein the first surface of the adhesive member is adhered to the mounting surface of the heat sink and the mounting fixture is adhered to at least a portion of the second surface of the adhesive member.

15. The heat sink apparatus of claim 1, wherein the mounting fixture is a cavitated mounting fixture comprising a cavity.

16. The heat sink apparatus of claim 15, further comprising a thermally conductive material positioned within the cavity.

17. The heat sink apparatus of claim 16, wherein at least a portion of the mounting fixture is adhered to the thermally conductive material.

18. The heat sink apparatus of claim 15, further comprising an adhesive member comprising a first surface and a second surface, wherein the first surface of the adhesive member is adhered to the mounting surface of the heat sink and the mounting fixture is adhered to at least a portion of the second surface of the adhesive member.

19. The heat sink apparatus of claim 15, wherein the cavitated mounting fixture further comprises a pressure-invertible dimple.

20. A heat sink assembly comprising the heat sink apparatus of claim 1 and a device attached to the heat sink.

21. The heat sink assembly of claim 20 further comprising an adhesive member comprising a first surface and a second surface, wherein the first surface of the adhesive member is adhered to the mounting surface of the heat sink and the mounting fixture is adhered to at least a portion of the second surface of the adhesive member.

22. The heat sink assembly of claim 21, wherein the device is adhered at least a portion of the second surface of the adhesive member.

23. The heat sink assembly of claim 20, wherein the mounting fixture comprises a dentate mounting fixture comprising a gap, a tooth, and a bridge.

24. The heat sink assembly of claim 23, wherein the device is positioned within the gap and aligned with at least one of the tooth and the bridge.

25. The heat sink assembly of claim 23, wherein a thermally conductive member is positioned within the gap.

26. The heat sink assembly of claim 25, wherein the thermally conductive member is adhered to the heat sink and the device is adhered to the thermally conductive member.

27. The heat sink assembly of claim 20, wherein the mounting fixture comprises a fenestrated mounting fixture comprising a window, a rail, and a stile.

28. The heat sink assembly of claim 27, wherein the device is positioned within the window and aligned with at least one of the rail and the stile.

29. The heat sink assembly of claim 27, wherein a thermally conductive member is positioned within the window.

30. The heat sink assembly of claim 29, wherein the thermally conductive member is adhered to the heat sink and the device is adhered to the thermally conductive member.

31. The heat sink assembly of claim 20, wherein the mounting fixture comprises a cavitated mounting fixture comprising a cavity.

32. The heat sink assembly of claim 31, wherein the electrical device is positioned within the cavity.

33. The heat sink assembly of claim 31, wherein a thermally conductive member is positioned within the cavity.

34. The heat sink assembly of claim 33, wherein the thermally conductive member is adhered to the heat sink and the device is adhered to the thermally conductive member.

35. A heat sink assembly of claim 31, wherein the cavitated mounting fixture further comprises a pressure-invertible dimple.

36. The heat sink assembly of claim 20, wherein the device comprises a component selected from the group consisting of an integrated circuit, capacitor, power amplifier, power transistor device, FETS, and MOSFETS.

37. The heat sink assembly of claim 20, further comprising a substrate, wherein the device is attached to the substrate.

38. The heat sink assembly of claim 37, wherein the substrate is a printed circuit board.

39. A method of mounting a device to a heat sink comprising
providing the heat sink apparatus of claim 7;
positioning the device within the gap;
aligning the device with at least one of the tooth or the bridge; and
adhering the device to the heat sink apparatus.

40. A method of mounting a device to a heat sink comprising
providing the heat sink apparatus of claim 11;
positioning the device within the window;
aligning the device with at least one of the rail or the stile; and
adhering the device to the heat sink apparatus.

41. A method of mounting a device to a heat sink comprising
providing the heat sink apparatus of claim 15;
positioning the device within the cavity; and
adhering the device to the heat sink apparatus.

42. A method of mounting a device to a heat sink comprising
providing the heat sink apparatus of claim 19;
positioning the device within the cavity; and
inverting the pressure-invertible dimple.

43. A method of making a heat sink apparatus comprising
providing a heat sink;
attaching at least one mounting fixture selected from the group consisting of a dentate mounting fixture, a fenestrated mounting fixture, and a cavitated mounting fixture to the heat sink.

44. The method of claim 43, wherein attaching the at least one mounting fixture to the heat sink comprises adhering the mounting fixture to a surface of the heat sink.

45. The method of claim 43, wherein attaching the at least one mounting fixture to the heat sink comprises applying at least one piece of single-sided tape to both the mounting fixture and the heat sink.

46. The method of claim 43, wherein attaching the at least one mounting fixture to the heat sink comprises engaging corresponding structural restraining features on the heat sink and the mounting fixture.

47. The method of claim 43, further comprising wrapping a portion of the at least one mounting fixture around an edge of the heat sink.

48. A method of making a heat sink apparatus comprising attaching a mounting fixture and at least one device to an adhesive member and attaching the adhesive member to a heat sink.
